(19) United States
(12) Patent Application Publication
(10) Pub. No.: US 2009/0260619 A1
(43) Pub. Date: Oct. 22, 2009

(54) AUTONOMOUS HELIOSTAT FOR SOLAR POWER PLANT

(75) Inventors: Lee Bailey, Lakewood, CA (US); Douglas W. Caldwell, Glendale, CA (US); Russell K. Jones, Manhattan Beach, CA (US)

Correspondence Address: CANADY & LORTZ LLP - BOEING, 2540 HUNTINGTON DRIVE, SUITE 205, SAN MARINO, CA, 91108, US

(73) Assignee: The Boeing Company, Chicago, IL (US)

(21) Appl. No.: 12/106,310

(22) Filed: Apr. 20, 2008

(51) Int. Cl. F24J 2/38; H01L 31/042; G05D 3/00

(52) U.S. Cl. 126/578; 136/246; 126/600; 353/3

(57) ABSTRACT

Heliostat operation under significantly reduced infrastructure requirements is disclosed. As part of a larger solar power generation system, a heliostat may function autonomously to track the sun and maintain constant reflection of solar radiation to a collection device for conversion to electrical power. The heliostat employs a local independent solar power supply to provide power to the positioning mechanism and controller for the heliostat. The controller receives sun position information from a sensor and/or a predetermined schedule. In addition, the controller for the heliostat may incorporate a wireless communications device for remote monitoring and directing operations of the heliostat.

### BACKGROUND OF THE INVENTION

1. Field of the Invention

This invention relates to systems and methods for operating heliostats for solar energy generation. Particularly, this invention relates systems and methods for operating heliostats reducing infrastructure requirements.

2. Description of the Related Art

In general, solar power generation involves the conversion of solar energy to electrical energy. This can be implemented through different technologies such as photovoltaics or heating a transfer fluid to produce steam to run a generator, for example. In some solar power generation systems one or more heliostats may be used to reflect solar radiation onto a collection point to enhance overall efficiency. Typically, each heliostat is controlled to track the sun and maintain reflection of the solar radiation on the collection point throughout the day. The solar radiation received at the collection point may be converted using any known technology. Typical conversion methods include thermal conversion using solar-generated steam or other working fluids, or direct conversion to electricity using photovoltaic cells.

On larger scales, solar power generation from concentrated sunlight may employ fields of multiple heliostats for solar energy collection. Each heliostat typically requires power distribution in order to drive the motor positioners and data communication in order to facilitate sun tracking control.

Costs associated with laying cables to each heliostat over a large area are significant and site specific. These costs include trenching, conduit, wire, wire installation, and wire maintenance. Because solar power facilities extend over very large areas to capture more radiation, such trenching, conduit and wire runs are very long and thus expensive. Because each solar power facility must be designed for site-specific conditions, standardized site or cabling designs have not proven effective at reducing costs. In addition, because soil conditions are often difficult to assess for an entire site (e.g., spanning many tens or hundreds of acres), unanticipated soil mechanics can quickly disrupt cost and schedule for a project. Finally, because solar power facilities are designed to operate over 30 or more years, infrastructure maintenance is also a significant economic consideration. Such geographically dispersed infrastructure is expensive to maintain, made worse when buried wiring is employed under the standard approach.

For a single large solar power plant (e.g., generating approximately 100 MW) the cost of building and maintaining this infrastructure would be in the millions of dollars. The solar power generation industry is revisiting heliostat-based architectures for cost-effective large-scale deployment. If heliostat-based architectures become the solution of choice, the annual savings from this invention could be in the tens of millions of dollars.

In view of the foregoing, there is a need in the art for systems and methods for efficient and cost-effective solar power generation. Particularly, there is a need for such systems and methods for improved heliostats used in solar power generation. These and other needs are met by the present invention as detailed hereafter.

### SUMMARY OF THE INVENTION

Embodiments of the present disclosure are directed to heliostat operation under significantly reduced infrastructure requirements. As part of a larger solar power generation system, a heliostat may function autonomously to track the sun and maintain constant reflection of solar radiation to a collection device for conversion to electrical power. The heliostat employs a local independent solar power supply to provide power to the positioning mechanism and controller for the heliostat. The controller receives sun position information from a sensor and/or a predetermined schedule. In addition, the controller for the heliostat may incorporate a wireless communications device for remote monitoring and directing operations of the heliostat.

A typical embodiment of the disclosure comprises a heliostat that includes a reflective surface for reflecting at least a first portion of received solar radiation to a collection device, a positioning mechanism coupled to the reflective surface for positioning the reflective surface, a controller for controlling the positioning mechanism to reflect at least the first portion of the received solar radiation to the collection device, and a solar power supply for converting a second portion of the received solar radiation to electrical power provided to the positioning mechanism and the controller. The solar power supply may include battery storage for the converted electrical power.

Typically, the solar power supply may include a photovoltaic panel for converting the second portion of the received solar radiation to the electrical power. The photovoltaic panel may be attached to the heliostat (e.g., to the reflective surface structure) or located anywhere nearby. In some notable embodiments, the photovoltaic panel may be disposed behind the reflective surface and the reflective surface comprises a dichroic surface for transmitting the second portion of the solar radiation through the reflective surface to the photovoltaic panel.

In further embodiments of the disclosure, the controller may comprise a wireless communication device for receiving sun location information remotely. Use of the wireless communication devices may be a key element for the control scheme for the heliostat. For example, the wireless communication device may be used to remotely receive sun location information from either a sensor or a predetermined schedule. In either case, the sun location information is applied to control proper positioning of the reflective surface.

Thus, in some embodiments of the disclosure, the controller may operate to control the positioning mechanism to reflect the first portion of the received solar radiation to the collection device applying sun location information from a sensor. The sensor is disposed with the heliostat. Alternately (or additionally), the controller may comprise a wireless communication device for receiving the sun location information from a remotely located sensor.

In some cases, the controller may operate to control the positioning mechanism to reflect the first portion of the received solar radiation to the collection device applying sun location information from a predetermined schedule. The controller may comprise a wireless communication device for receiving the sun location information from the predetermined schedule.

In a similar manner, a typical method of operating a heliostat may comprise reflecting at least a first portion of received solar radiation to a collection device with a reflective surface, positioning the reflective surface with a positioning mechanism coupled to the reflective surface, controlling the positioning mechanism with a controller to reflect at least the first portion of the received solar radiation to the collection device, and converting a second portion of the received solar radiation to electrical power with a solar power supply, the electrical power provided to the positioning mechanism and the controller. Method embodiments of the disclosure may be further modified consistent with apparatus and system embodiments of the disclosure described herein.

In addition, a heliostat apparatus in accordance with an embodiment of the disclosure may comprise a reflective means for reflecting at least a first portion of received solar radiation to a collection device, a positioning means coupled to the reflective surface for positioning the reflective surface, a controller means for controlling the positioning mechanism to reflect at least the first portion of the received solar radiation to the collection device, and a solar power supply means for converting a second portion of the received solar radiation to electrical power provided to the positioning mechanism and the controller. Apparatus embodiments of the disclosure may be further modified consistent with method embodiments of the disclosure described herein.

### BRIEF DESCRIPTION OF THE DRAWINGS

Referring now to the drawings in which like reference numbers represent corresponding parts throughout:

FIG. 1 illustrates an example solar power generation system employing a field of multiple heliostats that may operate in accordance with embodiments of the disclosure;

FIG. 2A is a functional block diagram of an example heliostat system operating in accordance with embodiments of the disclosure;

FIG. 2B is a schematic diagram of an example heliostat system operating in accordance with embodiments of the disclosure;

FIG. 2C illustrates an example heliostat system operating in accordance with embodiments of the disclosure;

FIG. 3A illustrates an example local solar power supply operating in accordance with embodiments of the disclosure;

FIG. 3B illustrates an example local solar power supply integrated into the heliostat with a dichroic mirror in accordance with embodiments of the disclosure; and

FIG. 4 is a flowchart of a method of operating a heliostat according to the disclosure.

### DETAILED DESCRIPTION OF THE PREFERRED EMBODIMENT

1. Overview

Embodiments in accordance with this disclosure addresses and mitigate the described economic issues and potentially eliminates all heliostat cabling and the costs associated therewith. A standardized hardware design can further simplify deployment activity and further mitigate site specific designs and the attendant risks and costs. Power and data distribution infrastructure can also be simplified and made more accessible compared with conventional distributed and buried infrastructure solutions so as to be more easily installed and maintained.

In accordance with one exemplary embodiment of the disclosure, each heliostat in a solar power generation system may be equipped with one or more heliostat local infrastructure nodes (HELINs) that each combine a local power supply (e.g., a solar power supply) and a wireless communications data transceiver. The local power supply will further include energy storage. The power supply can operate using solar energy (separated from the overall solar power generation system) that is collected during the daylight hours to power positioning mechanism motors, the controller circuitry, and the wireless data transceiver (e.g., a two-way communications device), thereby eliminating power wiring for the positioning mechanism motors and wireless data transceiver. The local energy storage can enable further operation of the heliostat when sunlight is unavailable. The wireless transceiver can be used to communicate commands and other telemetry between the heliostat and a central control station, thereby eliminating communication additional wiring. The local power supply may comprise solar energy collector such as a photovoltaic panel that may be either mounted directly on the heliostat or disposed nearby on the ground. In some embodiments, a photovoltaic panel for the local power supply may be integrated directly into the reflective surface of the heliostat, e.g., with a dichroic mirror.

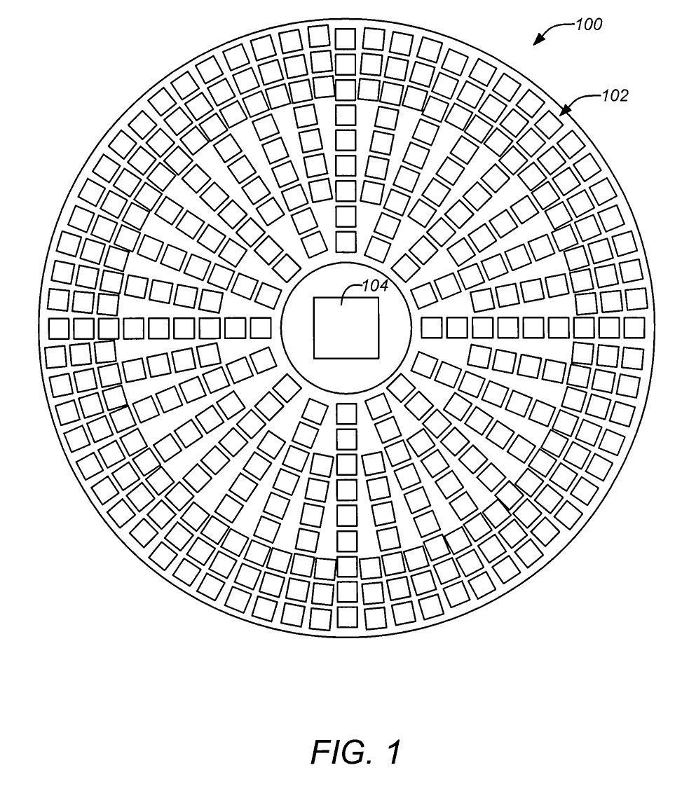

FIG. 1 illustrates an example solar power generation system 100 employing a field of multiple heliostats 102 that may operate in accordance with embodiments of the disclosure. The top view shows the collection device 104 comprises a central tower that receives solar radiation reflected from the encircling heliostats to a focal point near the top of the tower. The example system 100 shows 352 heliostats, however, those skilled in the art will appreciate that any number of heliostats may be used; the greater the number of heliostats, the more infrastructure savings can be expected. The reflected solar radiation heats water passing through the focal point of the collection device to drive a steam turbine generator to produce electrical power. Each of the heliostats 102 operates autonomously with its own power supply and positioner controller and may also include a wireless communication device as described hereafter to track the sun and maintain reflecting the solar radiation throughout the day.

Different types of heliostat nodes can take advantage of the reduced infrastructure in accordance with embodiments of the disclosure. Some system designs (such as that described in FIG. 1) may employ heliostat nodes using a common collection device for all the heliostat nodes, a single device positioned to receive reflected solar radiation from all the heliostat nodes. In other system designs, each heliostat node may include an individual collection device for receiving the reflected solar radiation. For example, an individual collection device may comprise steam pipes affixed to the front of a parabolic reflector on each heliostat. In this case, piping is required to carry the steam away to a steam turbine generator. (It is possible that each heliostat could have its own steam turbine generator but this is probably not cost effective.) In any case, both system types can benefit from eliminated infrastructure to support control and power of positioning of the heliostat nodes. Those skilled in the art will appreciate that the autonomous heliostat in accordance with the present disclosure may be used with almost any solar power generation system that requires sun tracking of one or more separate heliostats.

2. Autonomous Heliostat for Solar Power Plant

As described above, autonomous heliostats in accordance with embodiments of the disclosure can reduce the high costs and unpredictable nature of trenching large areas of land for cable runs for conventional heliostats employed with solar power generation systems. Embodiments of the disclosure can utilize available solar energy to power some portions of the overall system that would otherwise be a parasitic loss (e.g., tracking and pointing) on the system. In other words, power for these functions would otherwise need to come from the power generated by the central receiver, or from some other external power provider.

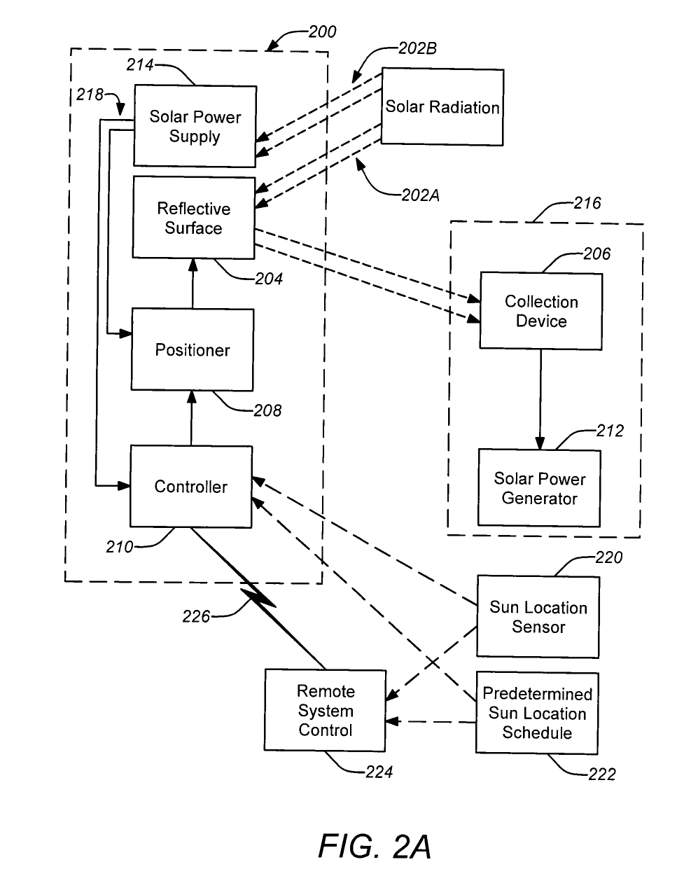

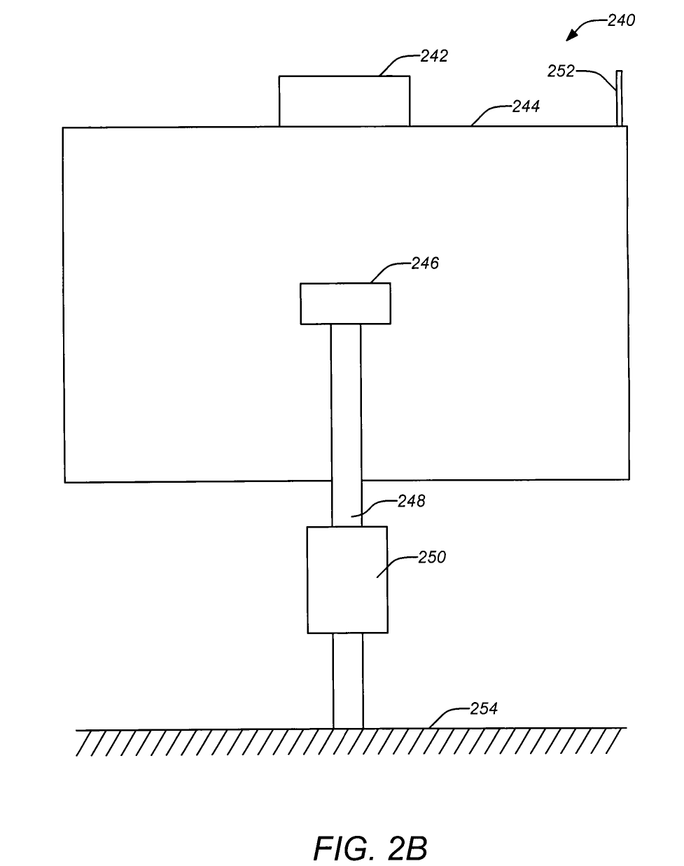

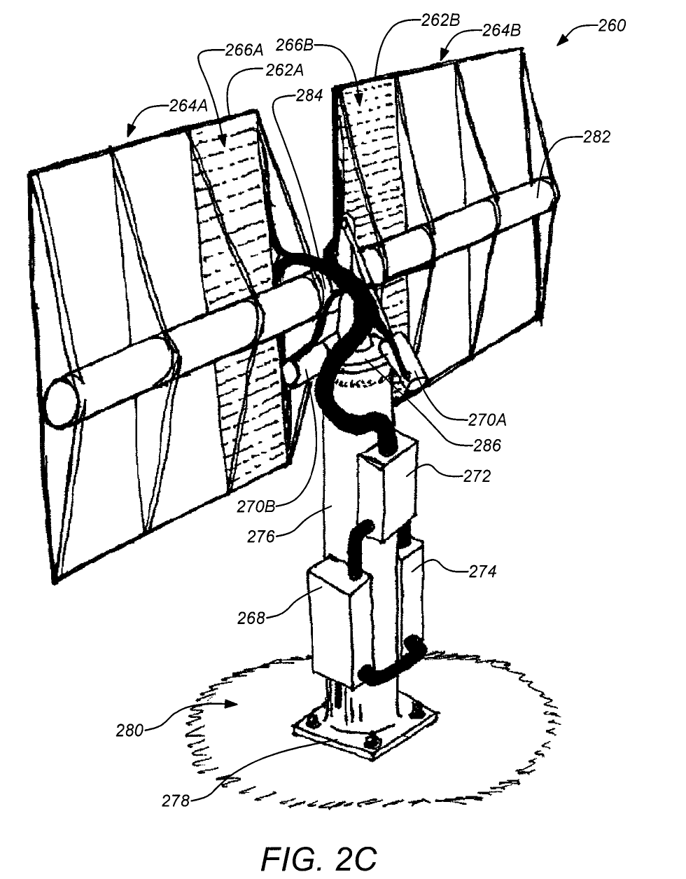

FIG. 2A is a functional block diagram of an example heliostat system 200 operating in accordance with embodiments of the disclosure. The fundamental function of the heliostat system 200 is to reflect received solar radiation 202A off a reflective surface 204 to a collection device 206 which feeds a solar power generator 212. The reflective surface 204 is coupled to a positioning mechanism 208 that manipulates the reflective surface 204 in order to track the sun as it moves across the sky and maintain reflection of the solar radiation 202A. In one example the positioning mechanism 208 may comprise two independent motor-driven angular positioning devices coupled in series that position about two substantially orthogonal axes, one for azimuth and one for elevation positioning. However, other types of positioning mechanisms 208 may also be used. For example, a single axis elevation positioning mechanism may be used in some systems (possibly sacrificing some efficiency) and in other systems one or more additional positioning axes may be added (e.g., a rotation positioning device).

The type and position of the collection device 206 depends upon the overall solar power generation system design. As discussed above, the collection device 206 feeds the solar power generator 212 and is a component of the primary solar power generation system 216 which converts solar energy to electrical power to be used elsewhere. The collection device 206 may be positioned to be fed by multiple autonomously operating heliostat systems 200 as in the example system 100 of FIG. 1. Alternately, the collection device 206 may be individual to each heliostat system. Embodiments of the disclosure are operable with almost any type of solar power generation system that uses one or more heliostats as will be understood by those skilled in the art.

Autonomous operation of the heliostat system 200 is afforded though the use of a solar power supply 214 local to each heliostat system 200. The solar power supply 214 is separate from the collection device 206 and solar power generator 212 of the primary solar power generation system 216. Typically, the solar power supply 214 will comprise a photovoltaic panel to convert a portion of the received solar radiation 202B to electrical power 218. (Note that the solar radiation received at the heliostat may be considered in two portions, a first reflected larger portion 202A and a second locally converted smaller portion 202B.) The electrical power 218 is used to drive the positioning mechanism 208 as well as the controller 210 described hereafter.

The positioning mechanism 208 is directed through controller 210 appropriate for the mechanism 208 type and design. The controller 210 is a programmable device which may operate the positioning mechanism 208 under closed loop control employing sensed position of each controlled axis of the mechanism 208 or under open loop control regularly updated against an absolute reference for each axis, e.g., a limit stop. The positioning mechanism 208 defines the orientation of the reflective surface 204. When the heliostat system 200 is installed, measurements are made to determine its orientation relative to the Earth and the collection device 206 (unless the collection device 206 is fixed to the heliostat 200, an option described above). Using this orientation information, proper positioning of the reflective surface 204 only requires the addition of sun location information.

Sun location information is typically obtained from two general techniques, sensing or calculation. A sun location sensor 220 may be employed to yield real-time information on the position of the sun. However, because the movement of the Earth relative to the sun is so well defined and predictable, it is also possible to predetermine a highly accurate sun location schedule 222. The only additional requirement to use the predetermined sun location schedule 222 is precise timekeeping. The controller 210 may use sun location information from a sun sensor 220, a predetermined sun location schedule 222, or a hybrid combination of both types of sun location information as will be understood by those skilled in the art. For example, solar position calculation algorithms have been made publicly available by the National Renewable Energy Laboratory and others as will be understood by those skilled in the art. In addition, a hybrid control system using both sun sensing and a predetermined position calculation can be found in I. Luque-Heredia, et al, Inspira's CPV Sun Tracking, Photovoltaic Concentration, Springer Verlag, in press.

The controller 210 directs the positioning mechanism 208 based on the current sun location information (and the defined orientation of the heliostat 200 and collection device 206, as applicable) to properly orient the reflective surface 204 to continuously reflect solar radiation 202A to the collection device 206 throughout the day. The sun location information may be provided by a predetermined schedule programmed directly into the controller 210 on the heliostat 200 (which also includes an accurate clock. Alternately, or additionally, the heliostat may employ its own local sun sensor 220 to provide sun location information. In these two cases, the heliostat system 200 operates autonomously in complete isolation. However, further embodiments of the disclosure may allow for some degree of outside control and monitoring over the autonomous operation of the heliostat system 200.

Remote control and monitoring of the heliostat system 200 without additional wired infrastructure may be accomplished by including a wireless communications device in the controller 210 for establishing a two-way communications link 226 between the controller 210 and a remote system controller 224. Typically, the remote system controller 224 provides a centralized control of all the heliostat systems operating in the field. All functions of the heliostat system 200 can be directed over the two-way communications link 226. The remote system controller 224 may also receive information regarding the operational status (e.g., status of the power supply 214, positioning mechanism 208, controller 210) from each of heliostat systems 200 over the two-way communications link 226, so that problems can be identified without requiring a technician to visit each heliostat system 200 first.

The remote system controller 224 may transmit the sun location information to the controller 210 of each heliostat system 200. In this case, if the sun location information is derived from a sensor 220, the sensor 220 may be a single sensor 220 employed for all the heliostat systems. (For extremely high precision, the sun location information from the single sensor 220 or the predetermined sun location schedule 222 may be adjusted for each heliostat system 200 based on its individual location relative to the sensor 220 or the location basis for the schedule 222. This adjustment may be conveniently made within the controller 210 for each heliostat system 200 because it is simply an individual constant added to the received global data.)

In one example embodiment of the disclosure, wireless communications is provided using an IEEE 802.11(g) Wi-Fi transceiver, with an antenna mounted collocated on the upper edge of the heliostat with the solar power supply (e.g., with the solar panel). Use of the 802.11(g) protocol allows many heliostats to be controlled from a single location while limiting licensing, bandwidth-sharing, and multi-path interference issues. The wireless communications method may be any one of many other options known to the art. For example, some other applicable wireless communications standards that may be employed include 802.11(a), 802.11(b), ZigBee, or mesh networks. Any other suitable communication standard may also be employed as will be understood by those skilled in the art. The antenna may be located on the ground or possibly collocated with the solar panel. In some cases reliable RF data transmission over heliostat sized fields where signal blocking and RF interference could be significant should be mitigated as part of a routine development testing.

FIG. 2B is a schematic diagram of an example heliostat system 240 operating in accordance with embodiments of the disclosure. In this exemplary embodiment of the disclosure, solar energy may be collected for the local solar power supply using a flat-plate photovoltaic panel 242 attached to an upper edge of the heliostat system 240. The large area of the heliostat 240 comprises the reflective surface 244. (Note that the figure shows the backside of the reflective surface 244.) The positioning mechanism 246 is coupled between the reflective surface 244 and a support post 248 and includes a drive and bearing assembly that manipulates the azimuth and elevation of the reflective surface 244. The support post 248 includes an electronics housing 250 that includes all electronics associated with the operation of the heliostat system 240. For example, the electronics housing 250 includes the controller electronics, motor drivers, photovoltaic power conditioning and battery for the local power supply and any wireless communications device. If a wireless communications device is employed, an antenna 252 (e.g., a 802.11(g) WiFi whip antenna) may be attached to the upper edge of the reflective surface 244 adjacent to the photovoltaic panel 242 to improve reception. Finally, the support post 248 may be mounted into the ground 254. As previously discussed, the heliostat system 240 operates without any additional infrastructure; no cabling or other physical infrastructure is coupled to the heliostat 240.

Because the heliostat system 240 is generally pointed in the direction of the sun in many applications, this configuration can reduce the required size of the photovoltaic panel 242. In addition, a further reduction in the photovoltaic panel 242 size may be achieved by using a low factor of solar concentration applied to the panel. Solar concentration is typically achieved through the use of a fixed reflector adjacent to the photovoltaic panel 242 for directing additional solar radiation to the photovoltaic panel 242 (similar to the principle function of the heliostat) as will be understood by those skilled in the art. For example, an auxiliary reflector can be used to reflect and concentrate additional solar radiation onto the photovoltaic panel 242 (e.g., by a concentration factor of two if the auxiliary reflector receives a projected area substantially equal to the photovoltaic panel 242 area). Again, this approach of attaching the photovoltaic panel 242 to the reflective surface 244 of the heliostat system 240 is facilitated by the fact that the reflective surface 244 will generally be pointing in the direction of the sun. Alternately, the photovoltaic panel 242 may also be disposed at other locations on the moving reflective surface 244 of the heliostat 240. Alternately, the photovoltaic panel 242 may be located on the ground adjacent to the heliostat 240, close enough to limit cabling issues, but far enough to avoid unacceptable shadowing from the powered heliostat or other nearby heliostats as they are positioned throughout the day.

FIG. 2C illustrates another example heliostat system 260 operating in accordance with embodiments of the disclosure. In general, this heliostat system 260 includes all the functional components previously described in reference to the systems 200, 240 of FIGS. 2A and 2B. However, one unique feature of this heliostat system 260 is that it incorporates dichroic mirrors 262A, 262B. Shown from the back, the heliostat system 260 comprises two large reflective surface sections 264A, 264B. Each of the reflective surface sections 264A, 264B includes a portion that formed from a dichroic mirror 262A, 262B. The dichroic mirrors 262A, 262B reflect a first portion of the incident solar radiation and filter a second portion of the incident solar radiation, allowing the second portion of the incident solar radiation to pass through the mirror 262A, 262B. Thin film photovoltaic panels 266A, 266B are disposed behind the dichroic mirrors 262A, 262B and receive the second portion of the incident solar radiation and convert it to electrical power as part of the solar power supply 268. The use of dichroic mirrors 262A, 262B enhances the efficient use of sun exposed area because the same exposed area may be used to reflect and convert different portions of the incident solar radiation. The converted electrical power is used to power the positioning mechanism (comprising azimuth positioning device 270A and elevation positioning device 270B) and the controller 272 for the heliostat system 260. The solar power supply 268 includes the battery storage 274.

In this example, the heliostat system 260 comprises a mast 276 and welded flange 278 that may be bolted to a structural support buried in the Earth 280. The mast 276 supports the azimuth positioning device 270A on a bearing 286 which allows for rotation of the entire upper assembly within a required range of motion. The reflective surface section 264A, 26B are supported by a cross member 282 which includes a central transverse bearing 284 coupled to the output of the azimuth positioning device 270A. Also coupled to the output of the azimuth positioning device 270A is the elevation positioning device 270B which rotates the cross member 282 about the transverse bearing 284. Those skilled in the art will appreciate that the heliostat system 260 of FIG. 2C is only one example configuration of the described components.

As described above, some embodiments of the disclosure may employ one or more dichroic mirrors integrated with photovoltaics using known technologies. For example, a thin film photovoltaic collector may be employed with a durable dichroic mirror. In one example, a thin film photovoltaic material may be optimized for the blue electromagnetic spectrum portion. The photovoltaic material can then be combined with the glass and backing material laminate of the heliostat mirror structure.

Specific heliostat designs in accordance with the disclosure may be readily developed by those skilled in the art using known wireless data transmission and photovoltaic technologies and standards. In addition, various relatively low tech and economical solar energy battery storage systems are readily available. Various off the shelf solutions may be readily employed within identifiable sizing limitations. A typical control architecture can be implemented that accounts for locally available stored energy for pointing demands of the heliostat during periods when direct solar radiation is unavailable.

3. Solar Power Supply

An important component of any autonomous heliostat embodiment of the disclosure is an independent power supply, e.g., a solar power supply. There are some options in the implementation of the solar power supply.

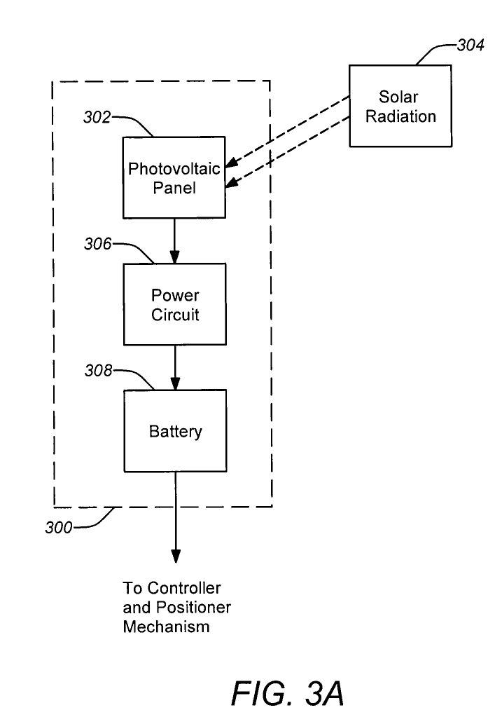

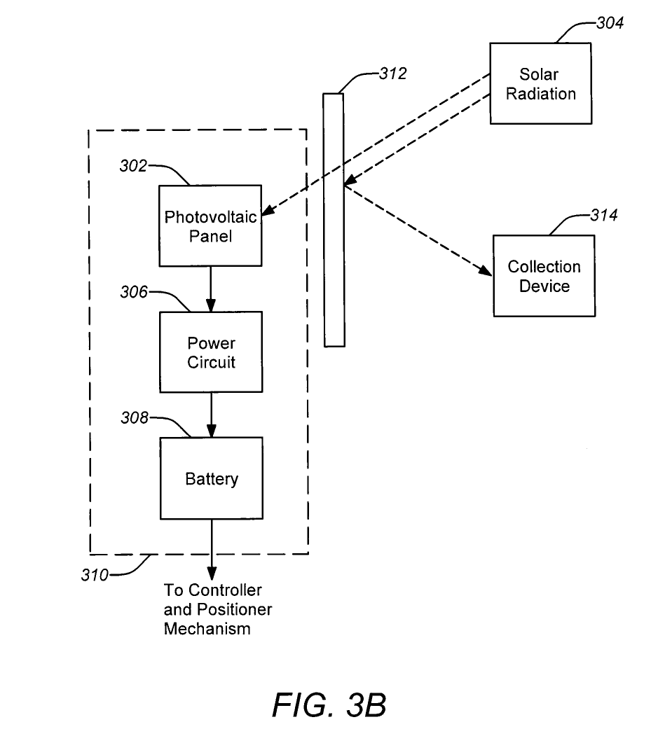

FIG. 3A illustrates an example local solar power supply 300 operating in accordance with typical embodiments of the disclosure as previously described. The solar power supply 300 comprises a photovoltaic panel 302 which receives a portion of the incident solar radiation 304 that is not being reflected by the heliostat. The photovoltaic panel 302 converts the received portion of the incident solar radiation 304 to electrical power which is coupled to a power circuit 306 for conditioning the electrical output of the photovoltaic panel 302. The electrical output of the power circuit 306 is coupled to the battery storage 308 which is also connected to the controller and positioning mechanism of the heliostat system.

FIG. 3B illustrates an example local solar power supply 310 integrated into the heliostat with a dichroic mirror 312 in accordance with embodiments of the disclosure. The photovoltaic panel 302, power circuit 306, and battery storage 308 of this solar power supply 310 operates essentially in the same manner as the solar power supply 300 of FIG. 3A. However, this power supply 310 operates in conjunction with a dichroic mirror 312 which reflects a first portion 324A of the received solar radiation 304 to a collection device 326 while a second portion 324B of the received solar radiation 304 is transmitted through the dichroic mirror 312 to the photovoltaic panel 302. Thus, the photovoltaic panel 302 receives on the transmitted second portion 324B of the received solar radiation 304 to be converted to electrical power.

As described above in some embodiments of the disclosure, solar energy may be collected using a thin film photovoltaic material mounted behind a dichroic mirror that allow a portion of the received solar radiation to pass through the dichroic mirror while reflecting the remaining solar radiation toward the central receiver. Thus, the thin film photovoltaic material uses only a filtered portion of the solar radiation. In one example, the dichroic mirror and thin film photovoltaic material may be matched to operate in the blue end of the visible spectrum to take advantage of the scattered light energy even on cloudy days. In this manner, there may be no need for separate structural support for the thin film photovoltaic material to compete for sun-exposed real estate with the main heliostat reflector. In some embodiments, all available reflective area of the heliostat can be used for the thin film photovoltaic material.

In yet another exemplary embodiment of the disclosure, solar energy is stored using a battery. This energy is used when the sun is not providing enough power to directly power the desired load. For example, the storage may be sized to provide minimally fourteen hours of operation including the following functions: repositioning to the desired position before sunrise; monitoring wireless data transmission for commands; transmitting data required for status reporting; executing a number of commands that would be expected to position the heliostat off of a useful collecting attitude (e.g., for stowage or cleaning). Additionally, this battery storage allows tracking of the sun during transient cloud passage. The storage provided may be smaller or larger than that which is required for fourteen hours. The storage medium might also or instead utilize “supercapacitors” or might use any other suitable electrical power storage technologies known in the art.

4. Method of Autonomous Operation of a Heliostat

Embodiments of the invention also encompass a method of autonomous operation of a heliostat consistent with the foregoing apparatus. In some cases the method of autonomous operation may be applied to existing heliostats retrofitted with a suitable appropriate power supply and controller (and optionally, a wireless transceiver).

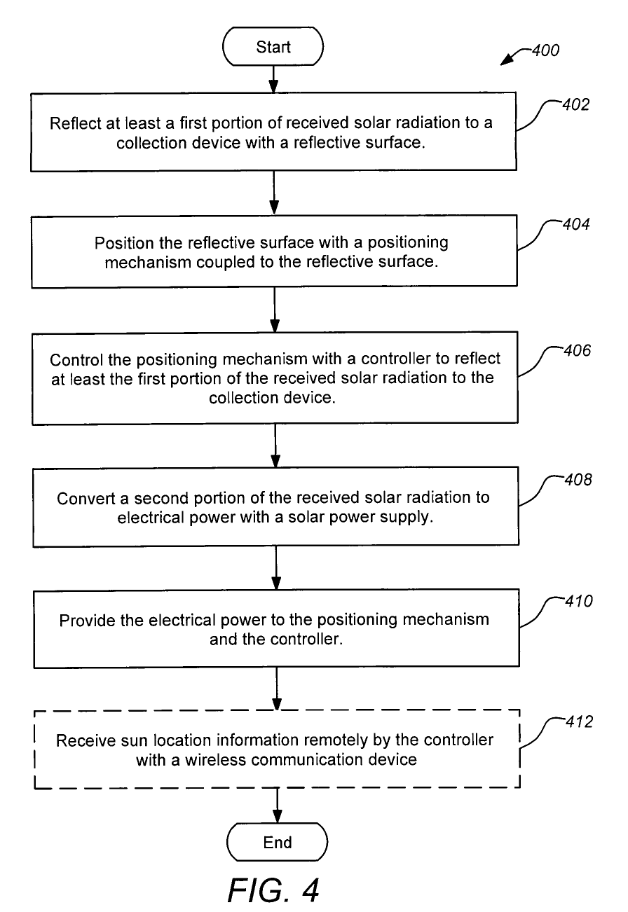

FIG. 4 is a flowchart of a method of operating a heliostat according to the disclosure. The method 400 begins with an operation 402 of reflecting at least a first portion of received solar radiation to a collection device with a reflective surface. Next, in operation 404, the reflective surface is positioned with a positioning mechanism coupled to the reflective surface. In operation 406, the positioning mechanism is controlled with a controller to reflect at least the first portion of the received solar radiation to the collection device. In operation 408, a second portion of the received solar radiation is converted to electrical power with a solar power supply. In operation 410, the electrical power is provided to the positioning mechanism and the controller. The method 400 may be further enhanced through optional operations in order to further develop the apparatus described in the foregoing section.

An important optional operation 412 for the method 400 of operating a heliostat (indicated by the dashed outline in FIG. 4) comprises receiving sun location information remotely by the controller with a wireless communication device. The sun location information is applied in controlling the positioning mechanism to reflect the first portion of the received solar radiation to the collection device. This sun location information may be provided from a sensor or from a predetermined schedule or from a combination of these types of sources.

This concludes the description including the preferred embodiments of the present invention. The foregoing description including the preferred embodiment of the invention has been presented for the purposes of illustration and description. It is not intended to be exhaustive or to limit the invention to the precise forms disclosed. Many modifications and variations are possible within the scope of the foregoing teachings. Additional variations of the present invention may be devised without departing from the inventive concept as set forth in the following claims.

What is claimed is:

1. A heliostat, comprising:
a reflective surface for reflecting at least a first portion of received solar radiation to a collection device;
a positioning mechanism coupled to the reflective surface for positioning the reflective surface;
a controller for controlling the positioning mechanism to reflect at least the first portion of the received solar radiation to the collection device; and
a solar power supply for converting a second portion of the received solar radiation to electrical power provided to the positioning mechanism and the controller.

2. The heliostat of claim 1, wherein the solar power supply comprises battery storage for the converted electrical power.

3. The heliostat of claim 1, wherein the solar power supply comprises a photovoltaic panel for converting the second portion of the received solar radiation to the electrical power.

4. The heliostat of claim 3, wherein the photovoltaic panel is disposed behind the reflective surface and the reflective surface comprises a dichroic surface for transmitting the second portion of the solar radiation through the reflective surface to the photovoltaic panel.

5. The heliostat of claim 1, wherein the controller comprises a wireless communication device for receiving sun location information remotely.

6. The heliostat of claim 1, wherein the controller operates to control the positioning mechanism to reflect the first portion of the received solar radiation to the collection device applying sun location information from a sensor.

7. The heliostat of claim 6, wherein the sensor is disposed with the heliostat.

8. The heliostat of claim 6, wherein the sensor is remotely located and the controller comprises a wireless communication device for receiving the sun location information from the remotely located sensor.

9. The heliostat of claim 1, wherein the controller operates to control the positioning mechanism to reflect the first portion of the received solar radiation to the collection device applying sun location information from a predetermined schedule.

10. The heliostat of claim 9, wherein the controller comprises a wireless communication device for receiving the sun location information from the predetermined schedule.

11. A method of operating a heliostat, comprising:
reflecting at least a first portion of received solar radiation to a collection device with a reflective surface;
positioning the reflective surface with a positioning mechanism coupled to the reflective surface;
controlling the positioning mechanism with a controller to reflect at least the first portion of the received solar radiation to the collection device; and
converting a second portion of the received solar radiation to electrical power with a solar power supply, the electrical power provided to the positioning mechanism and the controller.

12. The method of claim 11, further comprising storing the converted electrical power from the solar power supply in a battery storage.

13. The method of claim 11, wherein converting the second portion of the received solar radiation to the electrical power with the solar power supply is performed by a photovoltaic panel.

14. The method of claim 13, further comprising transmitting the second portion of the solar radiation through the reflective surface to the photovoltaic panel the photovoltaic panel disposed behind the reflective surface;
wherein the reflective surface comprises a dichroic surface.

15. The method of claim 11, further comprising receiving sun location information remotely by the controller with a wireless communication device;
wherein the sun location information is applied in controlling the positioning mechanism to reflect the first portion of the received solar radiation to the collection device.

16. The method of claim 11, further comprising receiving sun location information by the controller from a sensor;
wherein the sun location information is applied in controlling the positioning mechanism to reflect the first portion of the received solar radiation to the collection device.

17. The method of claim 16, wherein the sensor is disposed with the heliostat.

18. The method of claim 16, wherein the sun location information is received remotely by the controller with a wireless communication device.

19. The method of claim 1, wherein sun location information from a predetermined schedule is applied in controlling the positioning mechanism to reflect at least the first portion of the received solar radiation to the collection device.

20. The method of claim 19, further comprising receiving sun location information from the predetermined schedule by the controller with a wireless communication device.

21. A heliostat, comprising:
a reflective means for reflecting at least a first portion of received solar radiation to a collection device;
a positioning means coupled to the reflective surface for positioning the reflective surface;
a controller means for controlling the positioning mechanism to reflect at least the first portion of the received solar radiation to the collection device; and
a solar power supply means for converting a second portion of the received solar radiation to electrical power provided to the positioning mechanism and the controller.
